(19) United States
(12) Patent Application Publication
(10) Pub. No.: US 2025/0132192 A1
(43) Pub. Date: Apr. 24, 2025

(54) SEMICONDUCTOR PROCESSING METHOD

(71) Applicant: ASM IP Holding B.V., Almere (NL)

(72) Inventor: HeeSung Kang, Anyang-si (KR)

(21) Appl. No.: 19/001,463

(22) Filed: Dec. 25, 2024

Related U.S. Application Data
(62) Division of application No. 17/481,979, filed on Sep. 22, 2021, now Pat. No. 12,218,000.
(60) Provisional application No. 63/083,764, filed on Sep. 25, 2020.

(51) Int. Cl. H01L 21/764; H01L 21/768

(52) U.S. Cl. CPC H01L 21/764; H01L 21/7682

(57) ABSTRACT

A substrate processing method of easily forming an air gap includes: forming a first insulating layer having a first step coverage on a patterned structure including a first protrusion and a second protrusion; and forming, on the first insulating layer, a second insulating layer having a second step coverage lower than the first step coverage, wherein an air gap is formed between the first protrusion and the second protrusion by repeating the forming of the second insulating layer.

### CROSS-REFERENCE TO RELATED APPLICATIONS

This application is a divisional of, and claims priority to, U.S. patent application Ser. No. 17/481,979 filed Sep. 22, 2021 titled SEMICONDUCTOR PROCESSING METHOD; which claims priority to U.S. Provisional Patent Application Ser. No. 63/083,764 filed Sep. 25, 2020 titled SEMICONDUCTOR PROCESSING METHOD, the disclosures of which are hereby incorporated by reference in their entirety.

### BACKGROUND

### 1. Field

One or more embodiments relate to a substrate processing method, and more particularly, to a substrate processing method of forming an air gap inside a gap between patterned structures.

### 2. Description of the Related Art

In the manufacturing of a semiconductor device such as DRAM, the spacing between cells is getting narrower as the process becomes finer. Accordingly, a resistance capacitance (RC) delay due to a parasitic capacitance occurring between cells and a deterioration of a response time of a device due to the RC delay occur.

In order to solve this problem, a process of forming an air gap as a gap-fill material between electrodes has been considered to lower a dielectric constant of a buried material in an area between electrodes. The air gap process not only prevents an RC delay due to a low dielectric constant, but also prevents structural deformation problems such as film cracking and contact misalignment that may occur due to shrinkage of a gap-fill dielectric material.

The air gap process is used in various fields other than DRAM devices to achieve a low dielectric constant. For example, Korean Patent Publication No. 10-2010-0037212 discloses a process of forming an air gap in an insulating film arranged on a photodiode.

### SUMMARY

One or more embodiments include a structure in which thin films having very low step coverage are deposited using an overhang property of the thin films, thereby forming voids in a lower portion of a gap structure and cross-linking the thin films in an upper portion of the gap structure.

One or more embodiments include an optional thin film deposition method that minimizes a thin film deposition rate at the bottom of a gap structure and increases a thin film deposition rate at the top of the gap structure to maximize the effectiveness of an air gap process.

Additional aspects will be set forth in part in the description which follows and, in part, will be apparent from the description, or may be learned by practice of the presented embodiments of the disclosure.

According to one or more embodiments, a substrate processing method includes forming a first insulating layer having a first step coverage on a patterned structure including a first protrusion and a second protrusion; and forming, on the first insulating layer, a second insulating layer having a second step coverage lower than the first step coverage, wherein an air gap may be formed between the first protrusion and the second protrusion by repeating the forming of the second insulating layer.

According to an example of the substrate processing method, during the forming of the first insulating layer, pressure in a reaction space is maintained at a first pressure value, and the power of plasma is set to a first power value, and during the forming of the second insulating layer, the pressure in the reaction space is maintained at a second pressure value greater than the first pressure value, and the power of plasma may be set to a second power value less than the first power value.

According to another example of the substrate processing method, during the forming of the second insulating layer, a mean free path of gas supplied to the reaction space is reduced by the second pressure value, so that the gas is concentrated on upper portions of the first and second protrusions.

According to another example of the substrate processing method, during the forming of the second insulating layer, the amount of ions generated in the reaction space is reduced by the second power value, thereby reducing the ion density, and the ions may be concentrated on the upper portions of the first and second protrusions.

According to another example of the substrate processing method, during the forming of the first insulating layer, pressure in the reaction space may be maintained at about 5 Torr to about 11 Torr, and during the forming of the second insulating layer, pressure of the reaction space may be maintained at about 11 Torr to about 15 Torr.

According to another example of the substrate processing method, during the forming of the first insulating layer, the power of plasma may be set to about 500 W to about 1,500 W, and during the forming of the second insulating layer, the power of plasma may be set to about 100 W to about 400 W.

According to another example of the substrate processing method, the substrate processing method further includes removing by-products remaining between the first protrusion and the second protrusion, and the removing of the by-products may be performed while repeating the forming of the second insulating layer.

According to another example of the substrate processing method, during the removing of the by-products, an etching material having an etch selectivity with the second insulating layer may be used.

According to another example of the substrate processing method, the forming of the first insulating layer may include: forming a first silicon molecular layer on the first and second protrusions by supplying a first silicon-containing source gas; purging the first silicon-containing source gas; supplying a first reaction gas having reactivity with the first silicon molecular layer; and purging the first reaction gas.

According to another example of the substrate processing method, the forming of the second insulating layer may include: forming a second silicon molecular layer on the first insulating layer by supplying a second silicon-containing source gas; purging the second silicon-containing source gas; supplying a second reaction gas having reactivity with the second silicon molecular layer; and purging the second reaction gas.

According to another example of the substrate processing method, the substrate processing method may further include applying first hydrogen plasma on the first protrusion and the second protrusion before the forming of the second silicon molecular layer, wherein a hydrogen-rich insulating layer including hydrogen (H)-terminated sites may be formed by the first hydrogen plasma.

According to another example of the substrate processing method, a hydrogen monolayer may be formed by performing purging between the applying of the first hydrogen plasma and the forming of the second silicon molecular layer.

According to another example of the substrate processing method, during the applying of the first hydrogen plasma, pressure in the reaction space may be maintained at about 11 Torr to about 15 Torr and the power of plasma may be set at about 100 W to about 400 W, and due to the pressure and the power, the H-terminated sites may be formed more in the upper portions than in lower portions of the first protrusion and the second protrusion.

According to another example of the substrate processing method, the second silicon-containing source gas has reactivity with the H-terminated sites, whereby the second silicon molecular layer may be formed more in the upper portions than in the lower portions of the first protrusion and the second protrusion.

According to another example of the substrate processing method, during the supplying of the second reaction gas, second hydrogen plasma is applied, and due to the application of the second hydrogen plasma, a hydrogen content of the second insulating layer may increase and an etching resistance of the second insulating layer may decrease.

According to another example of the substrate processing method, the substrate processing method may further include planarizing an upper surface of the second insulating layer, wherein the planarizing may be performed using isotropic etching of the second insulating layer having reduced etch resistance.

According to another example of the substrate processing method, the substrate processing method may further include planarizing the upper surface of the second insulating layer, wherein the planarizing may be performed by a chemical mechanical polishing (CMP) process for the second insulating layer.

According to one or more embodiments, a substrate processing method includes depositing an insulating layer on a patterned structure having a first protrusion and a second protrusion to form an air gap between the patterned structure and the insulating layer, wherein an air gap may be formed between the first protrusion and the second protrusion by maintaining pressure in a reaction space such that a mean free path of gas supplied to the reaction space decreases and by setting power of plasma such that the amount of ions generated in the reaction space decreases.

According to one or more embodiments, a substrate processing method may include forming an air gap between a patterned structure and an insulating layer by setting power of plasma to about 100 W to about 400 W and applying the power for about 0.1 second to about 1 second to deposit the insulating layer having a step coverage of about 60% or less on the patterned structure.

According to an example of the substrate processing method, while the insulating layer is deposited on the patterned structure, pressure in a reaction space may be maintained at about 10 Torr to about 15 Torr.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart of a substrate processing method according to embodiments;

FIG. 2 is a flowchart of a substrate processing method according to embodiments;

FIGS. 3 and 4 are views showing a substrate processing method according to embodiments;

FIGS. 5 and 6 are views showing a substrate processing method according to embodiments;

FIGS. 7 and 8 are modified embodiments of the above-described embodiments of FIGS. 3 and 4 as other embodiments; and

FIGS. 9 and 10 are views illustrating step coverage (S/C) characteristics of a SiN film on a side surface compared to an upper surface (side/top) of a patterned structure according to an RF voltage and process pressure, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, one or more embodiments will be described more fully with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

In the disclosure, “gas” may include evaporated solids and/or liquids and may include a single gas or a mixture of gases. In the disclosure, a process gas introduced into a reaction chamber through a shower head may include a precursor gas and an additive gas. The precursor gas and the additive gas may typically be introduced as a mixed gas or may be separately introduced into a reaction space. The precursor gas may be introduced together with a carrier gas such as an inert gas. The additive gas may include a dilution gas such as a reaction gas and an inert gas. The reaction gas and the dilution gas may be mixedly or separately introduced into the reaction space. The precursor may include two or more precursors, and the reaction gas may include two or more reaction gases. The precursor may be a gas that is chemisorbed onto a substrate and typically contains metalloid or metal elements constituting a main structure of a matrix of a dielectric film, and the reaction gas for deposition may be a gas that is reactive with the precursor chemisorbed onto the substrate when excited to fix an atomic layer or a monolayer on the substrate. The term “chemisorption” may refer to chemical saturation adsorption. A gas other than the process gas, that is, a gas introduced without passing through the shower head, may be used to seal the reaction space, and it may include a seal gas such as an inert gas. In some embodiments, the term “film” may refer to a layer that extends continuously in a direction perpendicular to a thickness direction without substantially having pinholes to cover an entire target or a relevant surface, or may refer to a layer that simply covers a target or a relevant surface. In some embodiments, the term “layer” may refer to a structure, or a synonym of a film, or a non-film structure having any thickness formed on a surface. The film or layer may include a discrete single film or layer or multiple films or layers having some characteristics, and the boundary between adjacent films or layers may be clear or unclear and may be set based on physical, chemical, and/or some other characteristics, formation processes or sequences, and/or functions or purposes of the adjacent films or layers.

In the disclosure, the expression “containing an Si—N bond” may be referred to as characterized by an Si—N bond or Si—N bonds having a main skeleton substantially constituted by the Si—N bond or Si—N bonds and/or having a substituent substantially constituted by the Si—N bond or Si—N bonds. A silicon nitride layer may be a dielectric layer containing a Si—N bond, and may include a silicon nitride layer (SiN) and a silicon oxynitride layer (SiON).

In the disclosure, the expression “same material” should be interpreted as meaning that main components (constituents) are the same. For example, when a first layer and a second layer are both silicon nitride layers and are formed of the same material, the first layer may be selected from the group consisting of Si2N, SIN, Si3N4, and Si2N3 and the second layer may also be selected from the above group but a particular film quality thereof may be different from that of the first layer.

Additionally, in the disclosure, according as an operable range may be determined based on a regular job, any two variables may constitute an operable range of the variable and any indicated range may include or exclude terminated sites. Additionally, the values of any indicated variables may refer to exact values or approximate values (regardless of whether they are indicated as “about”), may include equivalents, and may refer to an average value, a median value, a representative value, a majority value, or the like.

In the disclosure where conditions and/or structures are not specified, those of ordinary skill in the art may easily provide these conditions and/or structures as a matter of customary experiment in the light of the disclosure. In all described embodiments, any component used in an embodiment may be replaced with any equivalent component thereof, including those explicitly, necessarily, or essentially described herein, for intended purposes, and in addition, the disclosure may be similarly applied to devices and methods.

Hereinafter, embodiments of the disclosure will be described with reference to the accompanying drawings. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

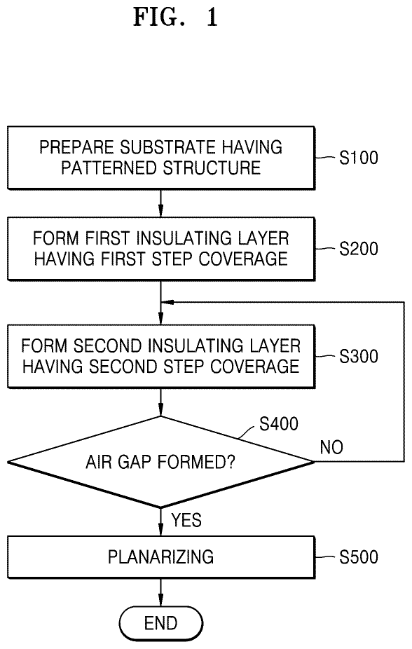

FIG. 1 is a flowchart of a substrate processing method according to embodiments.

Referring to FIG. 1, in operation S100, a substrate having a patterned structure is prepared. For example, a substrate may be loaded into a reaction space of a substrate processing apparatus. The substrate may be a semiconductor substrate, and may include, for example, any one of silicon, a silicon-on-insulator, silicon-on-sapphire, germanium, silicon-germanium, and gallium-arsenide.

The patterned structure is a non-flat structure, and may be a stepped structure including an upper surface, a lower surface, and a side surface connecting the upper surface and the lower surface. For example, the patterned structure may include a plurality of protrusions defined by a plurality of recesses. The patterned structure may be used to form an active area or may be used to form a gate pattern. For example, the patterned structure may include a first protrusion and a second protrusion, and each of the first protrusion and the second protrusion may include a gate electrode. When the patterned structure is used to implement a flash memory, each of the first protrusion and the second protrusion may further include a tunneling insulating layer.

In operation S200, when the substrate is prepared, a first insulating layer may be formed on the patterned structure. The first insulating layer may be formed to have a first step coverage. For example, the first step coverage of the first insulating layer may be 90% or more. That is, operation S200 of forming the first insulating layer may be performed such that a conformal thin film is deposited on the patterned structure.

Operation S200 of forming the first insulating layer may include supplying a first source gas and supplying a first reaction gas. In addition, during operation S200 of forming the first insulating layer, a thin film deposition process using plasma may be used. For example, at least one of plasma atomic layer deposition (PEALD), plasma chemical vapor deposition (PECVD), pulsed plasma chemical vapor deposition (Pulsed PECVD), and cyclic pulsed PECVD may be used.

For example, the first insulating layer may include silicon oxide, silicon nitride, or a combination thereof. In this case, operation S200 of forming the first insulating layer may include forming a first silicon molecular layer on the first and second protrusions by supplying a first silicon-containing source gas on the patterned structure, purging the first silicon-containing source gas, supplying a first reaction gas (e.g., oxygen and/or nitrogen) having reactivity with the first silicon molecular layer, and purging the first reaction gas.

At least one process parameter may be adjusted such that a conformal thin film is deposited during operation S200 of forming the first insulating layer. For example, pressure of gas in the reaction space may be reduced such that a mean free path of gas supplied to a patterned structure of a substrate in the reaction space is increased, and thus the pressure in the reaction space may be maintained at a first pressure value (e.g., 5 Torr to 11 Torr). In addition, power of plasma supplied to the reaction space may be increased such that the amount of ions generated in the reaction space increases to increase the ion density, and thus the power of the plasma may be set as a first power value (e.g., 500 W to 1500 W).

In operation S300, after the first insulating layer is formed on the patterned structure, a second insulating layer may be formed on the first insulating layer. The second insulating layer may be formed to have a second step coverage lower than the first step coverage. For example, the second step coverage of the second insulating layer may be 60% or less. By forming the second insulating layer of low step coverage, a void may be formed between the first insulating layer and the second insulating layer. Because air is usually contained in the void, the void is also referred to as an air gap.

Operation S300 of forming the second insulating layer may include supplying a second source gas and supplying a second reaction gas. In addition, during operation S300 of forming the second insulating layer, a thin film deposition process using plasma may be used. For example, at least one of PEALD, PECVD, pulsed PECVD, and cyclic pulsed PECVD may be used.

For example, the second insulating layer may include silicon oxide, silicon nitride, or a combination thereof. In this case, operation S300 of forming the second insulating layer may include forming a second silicon molecular layer on the first insulating layer by supplying a second silicon-containing source gas on the patterned structure, purging the second silicon-containing source gas, supplying a second reaction gas (e.g., oxygen and/or nitrogen) having reactivity with the second silicon molecular layer, and purging the second reaction gas.

At least one process parameter may be adjusted such that a lower step coverage thin film is deposited during operation S300 of forming the second insulating layer. For example, pressure of gas in a reaction space may be increased such that a mean free path of gas supplied to a patterned structure of a substrate in the reaction space is reduced, and thus the pressure in the reaction space may be maintained at a second pressure value (e.g., 11 Torr to 15 Torr). In addition, the power of the plasma supplied to the reaction space may be reduced such that the amount of ions generated in the reaction space decreases to reduce the ion density, and thus the power of the plasma may be set as a second power value (e.g., 100 W to 400 W).

In other words, during operation S300 of forming the second insulating layer, pressure of the reaction space may be maintained at the second pressure value greater than the first pressure value during the formation of the first insulating layer, and the power of the plasma may be set to the second power value less than the first power value during the formation of the insulating layer. Due to this relatively large pressure, gas is concentrated on upper portions of the first and second projections due to low mean free path, and the ion density is reduced by low power so that ions are concentrated on the upper portions of the first and second protrusions, and thus the second insulating layer having a low step coverage may be formed on the first insulating layer.

In operation S400, after the second insulating layer is formed, it may be determined whether an air gap is formed between the first insulating layer and the second insulating layer and between the first protrusion and the second protrusion. When an air gap is not formed, operation S300 of forming the second insulating layer is repeated. The formation of the second insulating layer may be repeated a certain number of times until an air gap is formed. That is, by repeating operation S300 of forming the second insulating layer, an air gap may be formed between the first protrusion and the second protrusion.

The first protrusion and the second protrusion of the patterned structure may be arranged spaced apart from each other at a narrow gap (e.g., 10 nm gap) in nanometer units. When the second insulating layer of a lower step coverage is deposited on the patterned structure due to this narrowly spaced arrangement structure, the second insulating layer may be formed in a large amount on an upper portion of an area between the first protrusion and the second protrusion, while the second insulating layer may be formed in a relatively small amount on a lower portion of the area between the first protrusion and the second protrusion.

Therefore, by repeating operation S300 of forming the second insulating layer, a structure (cross-linking) in which deposited second insulating layers are connected to each other is formed on the upper portion of the area between the first protrusion and the second protrusion, while a void may be formed on the lower portion of the area between the first protrusion and the second protrusion. An air gap formed by the void inside a gap between the protrusions may be formed by maintaining the pressure of the reaction space such that the mean free path of gas supplied to the reaction space decreases and/or by setting the power of the plasma such that the amount of ions generated in the reaction space decreases.

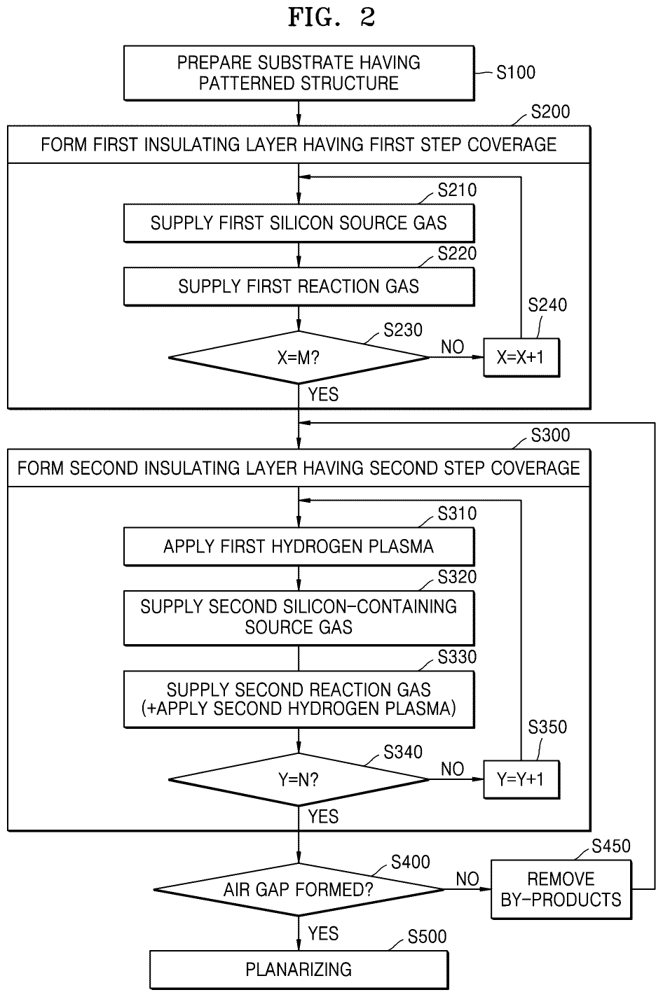

Thereafter, when it is determined that an air gap is formed, operation S500 of planarizing an upper surface of the second insulating layer may be performed. This planarizing may be performed by using a chemical mechanical polishing (CMP) process for the second insulating layer. In another embodiment, the planarizing may be performed using isotropic etching. In the case of isotropic etching, because planarization speed is lower than that of CMP, reducing of etching resistance of the second insulating layer may be additionally performed to increase the speed. This will be described in more detail in FIG. 2.

Although not shown in FIG. 1, in some embodiments, the substrate processing method may further include removing by-products remaining between the first protrusion and the second protrusion. In this case, the first insulating layer may perform a function of protecting the patterned structure while removing by-products. The removing of by-products will be described in more detail in FIG. 2.

FIG. 2 is a view of a substrate processing method according to embodiments. The substrate processing method according to the embodiments may be a variation of the substrate processing method according to the above-described embodiments. Hereinafter, repeated descriptions of the embodiments will not be given herein.

Referring to FIG. 2, the substrate processing method may include operation S200 of forming a first insulating layer, operation S300 of forming a second insulating layer, operation S400 of determining whether an air gap is formed, and operation S450 of removing by-products.

As described above, operation S200 of forming the first insulating layer may be performed using a thin film deposition process using plasma. For example, the first insulating layer may be silicon nitride, and in this case, a gas containing silicon may be used as a first silicon source gas. In addition, a gas containing nitrogen may be used as the first reaction gas. In another example, the first insulating layer may be silicon oxide, and in this case, a gas containing silicon may be used as the first silicon source gas. In addition, a gas containing oxygen may be used as the first reaction gas.

In order to form the first insulating layer, a first cycle including operation S210 of forming a first silicon molecular layer by supplying the first silicon source gas and operation S220 of supplying the first reaction gas under a first plasma atmosphere may be performed a plurality of times. In operations S230 and S240, this first cycle may be repeated a certain number of times (that is, until X becomes M), and then operation S300 of forming the second insulating layer may be performed.

Operation S300 of forming the second insulating layer, similar to operation S200 of forming the first insulating layer, may include a second cycle including operation S320 of forming a second silicon molecular layer by supplying a second silicon source gas and operation S330 of supplying a second reaction gas under a second plasma atmosphere. The second silicon source gas and the second reaction gas may be the same as or different from the first silicon source gas and the first reaction gas, respectively. The second insulating layer may be the same as the first insulating layer. For example, when the first insulating layer is silicon nitride, the second insulating layer may also be silicon nitride.

In some embodiments, prior to operation S320 of supplying the second silicon source gas to form the second silicon molecular layer, operation S310 of applying first hydrogen plasma on first and second protrusions may be performed. By applying the first hydrogen plasma, hydrogen (H)-terminated sites may be formed on the first insulating layer of the first protrusion and the second protrusion. That is, the first insulating layer (and a lower second insulating layer formed in the previous second cycle) may be converted into a hydrogen-rich insulating layer by the application of the first hydrogen plasma.

During operation S310 of applying the first hydrogen plasma, process conditions may be adjusted such that more hydrogen ions are formed in the upper portions of the first and second protrusions than in lower portions of the first and second protrusions. For example, the pressure in the reaction space may be maintained at 11 Torr to 15 Torr such that the mean free path of hydrogen gas supplied to the reaction space decreases, and the power of the plasma may be set to 100 W to 400 W such that the amount of hydrogen ions generated in the reaction space is reduced. Due to the pressure and the power condition above, the H-terminated sites may be formed more in the upper portions of the first protrusion and the second protrusion than in the lower portions of the first protrusion and the second protrusion.

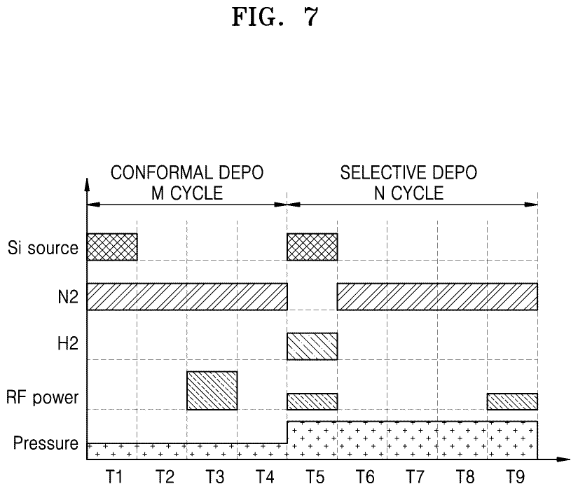

After operation S310 of applying the first hydrogen plasma, operation S320 of supplying a second silicon-containing source gas may be performed. Because the H-terminated sites serve as bonding sites reactive with the second silicon-containing source gas, the second silicon molecular layer may be formed more in the upper portions of the first protrusion and the second protrusion than in the lower portions of the first protrusion and the second protrusion. In an alternative embodiment, operation S310 of applying the first hydrogen plasma and operation S320 of supplying the second silicon-containing source gas may be performed simultaneously (sec FIG. 7).

In an alternative embodiment, although not shown in FIG. 2, purging (not shown) may be performed between operation S310 of applying the first hydrogen plasma and operation S320 of supplying the second silicon-containing source gas. A hydrogen monolayer may be formed on the first insulating layer (and the lower second insulating layer formed by the previous second cycle (e.g., Y-1 cycle, if a new second insulating layer is formed during Y cycle) by the purging. In addition, a hydrogen gas remaining inside a gap may be removed through the purging.

After operation S320 of supplying the second silicon source gas to form the second silicon molecular layer, operation S330 of supplying the second reaction gas is performed. In some embodiments, during operation S330 of supplying the second reaction gas, the second hydrogen plasma may be applied. Due to the application of the second hydrogen plasma, hydrogen content of the second insulating layer may increase, and as a result, etching resistance of the second insulating layer may decrease. The second insulating layer having reduced etch resistance may be suitable for planarizing through isotropic etching such as wet etching.

In order to form the second insulating layer, a second cycle including operation S320 of forming a second silicon molecular layer by supplying the second silicon source gas and operation S330 of supplying the second reaction gas under a second plasma atmosphere may be performed a plurality of times. In operations S340 and S350, this second cycle may be repeated a certain number of times (i.e., until Y becomes N), and thereafter, operation S400 of determining whether an air gap is formed may be performed.

Both operation S200 of forming the first insulating layer and operation S300 of forming the second insulating layer may be common in that an insulating layer containing a Si—N bond is formed. In this case, in some embodiments, operation S200 of forming the first insulating layer and operation S300 of forming the second insulating layer may be performed in-situ in an identical reactor. However, detailed process parameters for forming the insulating layer containing the Si—N bond may be different. For example, as described above, the pressure of the reaction space and the power of the plasma may be set differently such that insulating layers having different step coverages are formed.

As another example, in some embodiments, different types of gases may be supplied during operation S200 of forming the first insulating layer and operation S300 of forming the second insulating layer. In more detail, during operation S300 of forming the second insulating layer, a material having a relatively high hydrogen content may be used as the second silicon source gas. In addition, a nitrogen source having a high hydrogen content or containing hydrogen may be used as the second reaction gas. In other words, the hydrogen contents of the second silicon source gas and the second reaction gas used in operation S300 of forming the second insulating layer may be higher than the hydrogen contents of the first silicon source gas and the first reaction gas used in operation S200 of forming the first insulating layer.

Due to the difference in hydrogen content, the first insulating layer (i.e., first silicon nitride layer) having the first step coverage and the second insulating layer (i.e., second silicon nitride layer) having the second step coverage lower than the first step coverage may have different densities and wet etch rates (WERs). As a specific example, by supplying a second reaction gas including NH3 included in the second reaction gas during operation S300 of forming the second insulating layer, a larger amount of hydrogen component may be included in the second insulating layer. Accordingly, the second insulating layer may have a relatively small number of Si—N bonds, and accordingly, the second insulating layer may have a high WER and low etch resistance.

Referring back to FIG. 2, operation S400 of determining whether an air gap is formed is performed. Operation S400 of determining whether an air gap is formed may include determining whether an air gap forming cycle including operation S300 of forming the second insulating layer and operation S450 of removing by-products is performed a certain number of times. That is, the air gap forming cycle including operation S300 of forming the second insulating layer and operation S450 of removing by-products may be repeated a certain number of times, and then planarizing may be performed.

When an air gap is not formed under the second insulating layer (i.e., when the second insulating layer on the first protrusion and the second insulating layer on the second protrusion are not connected to each other), operation S300 of forming the second insulating layer is performed again. In an alternative embodiment, before performing operation S300 of forming the second insulating layer, operation S450 of removing by-products remaining between the first protrusion and the second protrusion of the patterned structure may be performed. That is, the removing of by-products may be performed while repeating operation S300 of forming the second insulating layer.

Due to a narrow gap between the first protrusion and the second protrusion and deposition of the second insulating layer having a low step coverage, by-products may remain between the first protrusion and the second protrusion. For example, at least one of a second silicon source gas, a second silicon molecule detached from or dangling-bonded to a second silicon molecule layer formed on the inner surface of a gap between the first and second protrusions and molecular fragments comprising the same, and a second reaction gas may remain between the first protrusion and the second protrusion, and this by-product may not be removed despite the purging performed after the supplying of the second reaction gas.

Therefore, in order to remove the by-product, isotropic etching may be used. For example, during the removing of the by-product, wet etching may be performed using an etching material having an etch selectivity with the second insulating layer. By isotropic etching such as wet etching, by-products inside the gap of the patterned structure remaining after the purging may be removed.

In operation S400 of determining whether an air gap is formed, when an air gap is formed under the second insulating layer (i.e., when the second insulating layer on the first protrusion and the second insulating layer on the second protrusion are connected to each other), operation S500 of planarizing the second insulating layer may be performed as a subsequent operation. The planarizing may be performed using CMP on the second insulating layer. In some other embodiments, the planarizing may be performed using isotropic etching of the second insulating layer having reduced etching resistance (i.e., with increased WER). As described above, in operation S330, second hydrogen plasma may be applied to form the second insulating layer having reduced etch resistance.

Although the second insulating layer is formed after the first insulating layer is formed in the embodiments of FIGS. 1 and 2, in some embodiments, the second insulating layer may be formed on the patterned structure without forming the first insulating layer. That is, an insulating layer having a low step coverage (e.g., 60% or less step coverage) may be deposited on a patterned structure having a first protrusion and a second protrusion to form an air gap between the patterned structure and the insulating layer.

In this case, as described above, power of plasma may be set relatively low (e.g., 100 W to 400 W) such that the insulating layer having a low step coverage is formed, and such power may be applied for a short time (0.1 second to 1 second). In addition, pressure of a reaction space while the insulating layer is deposited on the patterned structure may be kept relatively high (e.g., 10 Torr to 15 Torr) such that the mean free path of gas supplied to the reaction space is reduced.

As described above, according to embodiments, an air gap may be formed in a gap between patterned structures by performing selective deposition on the patterned structures. In more detail, by adjusting the amount of process pressure and applied RF power, selective deposition on the patterned structure and formation of an air gap inside the gap may be more easily achieved.

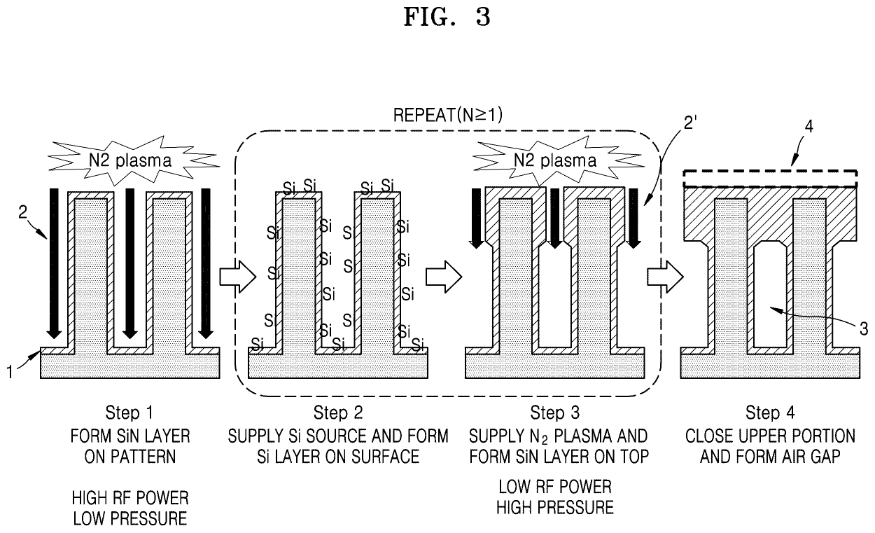

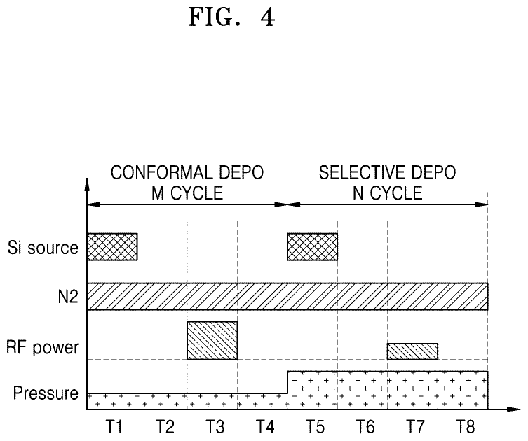

FIGS. 3 and 4 are views of a substrate processing method according to embodiments. The substrate processing method according to the embodiments may be a variation of the substrate processing method according to the above-described embodiments. Hereinafter, repeated descriptions of the embodiments will not be given herein.

The disclosure proposes a processing method for forming an air gap in a gap. In more detail, a 2-step plasma process is proposed as a method for selectively controlling a deposition rate of thin films between gap structures.

Distribution of plasma ion flux according to the depth of a gap structure is highly dependent on process pressure. When the process pressure is sufficiently low, the number of collisions between ions and gases is relatively small, and thus an MFP (mean free path) of ions becomes longer and ions are distributed to a lower portion of a stepped structure. However, when the process pressure is high, the number of collisions between ions and gases is relatively high and the MFP of ions is short, and thus ions are mainly concentrated in an upper portion of the gap structure. Also, this phenomenon is more pronounced by applied RF power. In other words, when high RF power is applied, the amount of generated ions is large and the ion density is high, and thus ions may reach the bottom of the gap structure, whereas when low RF power is applied, the amount of generated ions is relatively small and the ion density is low, and thus ions are mainly distributed in the upper portion of the gap structure. Therefore, when selectively adjusting film quality of the upper portion of the gap structure, an appropriate combination of the process pressure and the applied RF power is required. For example, under low process pressure and high RF power, a film is formed up to the inner surface of the gap, whereas under high process pressure and low applied RF power, a film is mainly formed on the upper surface of the gap.

Referring to FIG. 3, a detailed description of each operation is as follows.

1. First step (Step 1): A thin film 1 is deposited on a patterned structure including a gap. In this embodiment, a SiN film is uniformly deposited. The deposition proceeds by supplying a silicon-containing source gas and an activated nitrogen-containing reaction gas through a plasma atomic layer deposition (PEALD) or pulsed PECVD or a combination thereof. In this step, high RF power is applied at low process pressure to supply activated nitrogen reaction gas 2 (N2 plasma flux) to the inner surface and bottom of a gap structure. The film deposited in this step serves as a protective film for protecting the patterned structure from an etching material during gap etching performed between the third step and the fourth step to be described later.

2. Second step (Step 2): Si source gas is supplied to the SiN film deposited on the patterned structure to form a silicon (Si) source molecular layer. In the second step, a Si source monolayer may be formed by supplying a Si source gas and then further adding a purge step.

3. Third step (Step 3): A SiN film is formed by supplying an activated nitrogen-containing reaction gas on the patterned structure in which the Si source molecular layer is formed. This step is carried out under low RF power and high process pressure such that an activated nitrogen reaction gas 2′ mainly flows in the upper portion of the patterned structure, and thus a SiN thin film is selectively deposited on the upper portion of the patterned structure compared to the inside of the patterned structure. The second and third steps are repeated several times. In another embodiment, a purge step is added between the second and third steps, and after the third step, and thus the SiN thin film is selectively deposited on the upper portion of the patterned structure by a plasma atomic layer deposition method.

4. Fourth step (Step 4): By repeating the second and third steps, SiN films formed on the upper portion of the patterned structure are connected to each other to form a void 3 therein. After this step, a film 4 having a certain thickness may be further removed from the patterned structure in a CMP step.

When the second and third steps are repeated by performing an additional etching process between the third and fourth steps, reaction by-products that piled-up in a gap inner space 3 between pattern structures may be removed. Because the SiN film (i.e., the SiN film as a protective film) is uniformly formed on a gap surface in the first step, damage to the patterned structure by the etching material may be prevented.

Referring to FIG. 4, steps T1 to T4 correspond to the first step of FIG. 3 and represent a step of uniformly depositing a SiN film on a patterned structure. This step is repeated M times. The steps T5 to T8 correspond to the second to third steps of FIG. 3 and represent a step of selectively depositing a SiN film on an upper portion of the patterned structure. This step is repeated N times. As shown in FIG. 4, the first step of FIG. 3 is referred to as a conformal deposition step, and the second to third steps of FIG. 3 are referred to as a selective deposition step. The conformal deposition step and the selective deposition step may be performed in one reactor in an in-situ continuous process or in another reactor in an ex-situ process. During the ex-situ process, after the conformal deposition step is performed in one reactor, a substrate may be transferred to another reactor to perform the selective deposition step.

The disclosure according to the embodiments of FIGS. 3 and 4 has a technical effect of facilitating selective deposition on a patterned structure by controlling the amount of applied RF power and the process pressure.

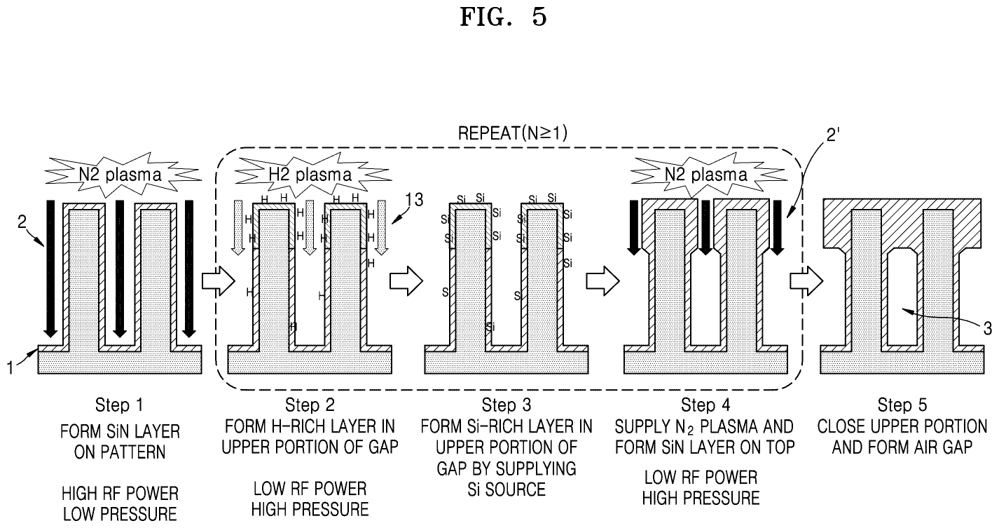

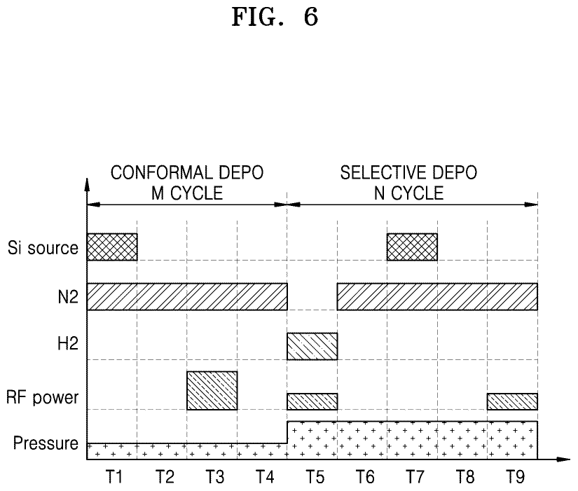

FIGS. 5 and 6 are views of a substrate processing method according to embodiments; the substrate processing method according to the embodiments may be a variation of the substrate processing method according to the above-described embodiments. Hereinafter, repeated descriptions of the embodiments will not be given herein.

Because the first step shown in FIG. 5 corresponds to the first step of FIG. 3, a description thereof will not be given herein. A detailed description of the second to fifth steps of FIG. 5 is as follows.

1. Second step (Step 2): In the second step, after forming a SiN thin film on the surface of the gap in the first step, hydrogen plasma is applied. In this step, a hydrogen plasma flux 13 is formed mainly in the upper portion of the patterned structure by carrying out under a low RF applied voltage and high process pressure to form a hydrogen (H)-rich film in the upper portion of the patterned structure. The H-rich film acts as an H-terminated sites, and the H-terminated sites have high reactivity with a silicon-containing source gas, thus becoming bonding sites. In another embodiment, a hydrogen monolayer may be formed by adding a purge step after the second step.

2. Third step (Step 3): A silicon source gas is supplied. As mentioned in the second step, the silicon source gas chemically reacts with the H-terminated sites formed in the upper portion of the patterned structure to form a silicon layer. In another embodiment, a Si monolayer may be formed by adding a purge step after the third step.

3. Fourth step (Step 4): By supplying an activated nitrogen reaction gas, the SiN film is formed by chemically reacting with the silicon layer in the upper portion of the patterned structure. In this step, a nitrogen plasma flux 2′ is formed mainly in the upper portion of the patterned structure by proceeding under a low RF applied voltage and high process pressure to form the SiN film in the upper portion of the patterned structure.

4. Fifth step (Step 5): The second, third and fourth steps are repeated several times. Through the repetition, SiN films formed on the upper portion of the patterned structure are connected to each other to form the void 3 therein. After this step, the film 4 having a certain thickness (the film 4 of the fourth step in FIG. 3) may be removed from the patterned structure in a CMP step.

5. Additional step: An etching process is additionally performed between the fourth and fifth steps to remove reaction by-products piled-up in the gap inner space 3 when repeating the third and fourth steps. Because the SiN film is uniformly formed on a gap surface in the first step, damage to the patterned structure by an etching material may be prevented. In addition, after the fifth step, a portion of the film deposited on an upper portion of the gap may be removed using a CMP process (see step 4 in FIG. 3).

FIG. 6 shows a process sequence of the embodiment of FIG. 5.

Referring to FIG. 6, steps T1 to T4 correspond to the first step of FIG. 5 and represent a step of uniformly depositing a SiN film on a patterned structure. This step is repeated M times. Steps T5 to T9 correspond to the second to fourth steps of FIG. 5 and represent a step of forming a H-rich area and a Si-rich area in an upper portion of the patterned structure, and selectively depositing a SiN film in the corresponding area. This step is repeated N times. As shown in FIG. 6, the first step of FIG. 5 is referred to as a conformal deposition step, and the second to fourth steps of FIG. 5 are referred to as a selective deposition step. The conformal deposition step and the selective deposition step may be performed in one reactor in an in-situ continuous process or in another reactor in an ex-situ process. During the ex-situ process, after the conformal deposition step is performed in one reactor, a substrate may be transferred to another reactor to perform the selective deposition step. In the selective deposition step of FIG. 6, by adding a purge step T6 after step T5 in which hydrogen is supplied, a hydrogen monolayer may be formed in the upper portion of the patterned structure. In addition, by adding a purge step T8 after step T7 in which a silicon-containing gas is supplied, a Si monolayer may be formed in the upper portion of the patterned structure.

Meanwhile, during step T5, supply of a nitrogen gas may be stopped. The nitrogen gas may be continuously supplied during the conformal deposition step and the selective deposition step to serve as a reactive purge gas (see FIG. 4). That is, the nitrogen gas may function as a purge gas while plasma is not applied, and may be activated when plasma is applied to be used in forming a nitride film. In contrast, in the embodiment of FIG. 6, the supply of a reactive purge gas such as a nitrogen gas is stopped during step T5, and by stopping the supply of the reactive purge gas, a hydrogen gas more easily reaches the patterned structure. Therefore, there is a technical effect that formation of H-terminated sites reactive with a silicon source on the patterned structure is further promoted.

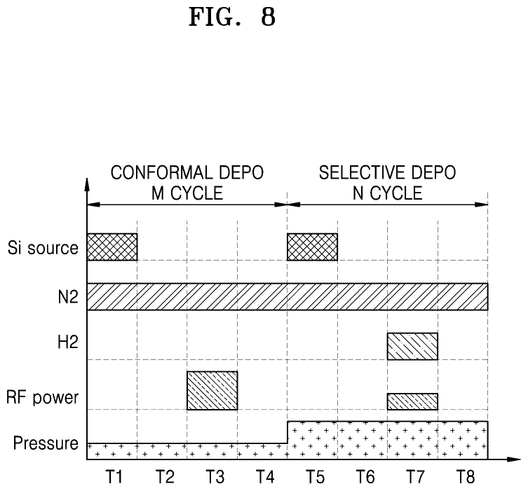

The disclosure according to the embodiments of FIGS. 5 to 6 has a technical effect that can facilitate selective deposition in the upper portion of the patterned structure by controlling the process pressure and the applied RF power and forming an H-rich layer highly reactive with a silicon source gas in the upper portion of the patterned structure. FIGS. 7 and 8 are modified embodiments of the above-described embodiments of FIGS. 5 and 6 as other embodiments.

Referring to FIG. 7, in an alternative embodiment, in step T5, a silicon source and a hydrogen mixed gas may be supplied and activated together. That is, the second step of applying the hydrogen plasma and the third step of supplying the silicon source of FIG. 5 may be simultaneously performed. In the embodiment of FIG. 6 described above, the silicon source is supplied (T7 in FIG. 6) after the application (T5 in FIG. 6) of the hydrogen plasma, but in the embodiment of FIG. 7 the silicon source and the hydrogen plasma may be supplied simultaneously. Therefore, there is a technical effect that may further improve the substrate processing speed and throughput.

Referring to FIG. 8, in an alternative embodiment, in step T7, a mixed gas of nitrogen and hydrogen is supplied and activated together in a selective deposition step. A hydrogen gas is a process variable that affects wet etch resistance of a thin film. When the hydrogen content is high, etch resistance of a film decreases, and when the hydrogen content is low, the etch resistance of the film increases. Accordingly, there is a technical effect of controlling etching resistance of a SiN film deposited on the upper portion of the patterned structure and improving suitability with subsequent processes. For example, when removing a patterned upper structure after the fourth step of FIG. 5, an etching process may be more accurately performed by wet etching instead of CMP.

In another embodiment, when the etching process is performed between the fourth and fifth steps of FIG. 5 to remove reaction by-products piled-up in the gap inner space 3, there is a technical effect that may facilitate the removal of reaction by-products by controlling etching of a film in an upper portion of the pattern structure.

Table 1 below shows experimental conditions of the embodiments according to FIGS. 3 to 6.

TABLE 1

| Precursor | Si-containing gas | |
|---|---|---|
| Susceptor | 100° C. to 550° C. (preferably 450° C. to 550° C.) | |
| temperature | | |
| (° C.) | | |
| Process | Conformal | 5 Torr to 11 Torr (preferably |
| pressure (Torr) | deposition step | 8 Torr to 10 Torr) |
| | Selective | 11 Torr to 15 Torr (preferably |
| | deposition step | 12 Torr to 14 Torr) |
| Reaction gap | 10 mm to 15 mm (preferably 11 mm to 13 mm) | |
| between | | |
| showerhead and | | |
| substrate (mm) | | |
| Gas flow (sccm) | Source carrier Ar | 2,000 sccm to 6,000 sccm |
| | | (preferably 3,000 sccm to |
| | | 5,000 sccm) |
| | Reactant N2 | 10,000 sccm to 30,000 sccm |
| | | (preferably 15,000 sccm to |
| | | 25,000 sccm) |
| | Hydride (H₂) | 5 sccm to 50 sccm (preferably |
| | | 10 sccm to 40 sccm) |
| Process step & | Source feeding | 0.1 seconds to 1.0 seconds |
| time | (t0~t1) | (preferably 0.2 seconds to 0.8 |
| | | seconds) |
| | Source purge | 0.1 seconds to 1.0 seconds |
| | (t1~t2) | (preferably 0.2 seconds to 0.8 |
| | | seconds) |
| | RF ON (t2~t3) | 0.1 seconds to 1.0 seconds |
| | | (preferably 0.2 seconds to 0.8 |
| | | seconds) |
| | Purge (t3~t4) | 0.1 seconds to 1.0 seconds |
| | | (preferably 0.2 seconds to 0.8 |
| | | seconds) |
| RF power | RF frequency | 13.56 MHz to 27.12 MHz |
| | Conformal | 500 W to 1,500 W (preferably |
| | deposition step | 700 W to 1,000 W) |
| | Selective deposition | 100 W to 400 W (preferably |
| | step | 150 W to 350 W) |

In an embodiment, a Si-containing gas as a first reaction gas may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, Si H₂[N(Et)(Me)]₂; AHEAD, Si₂(NHEt)₆; TEAS, Si(NHEt)₄; Si₃H₈; DCS, SiH₂Cl₂; SiHI₃; and SiH₂I₂, or a derivative thereof, or a mixture thereof. A nitrogen-containing gas as a second reaction gas may include at least one of N₂, NH₃, NH₄⁺, N₂O, or NO₂, or a mixture thereof.

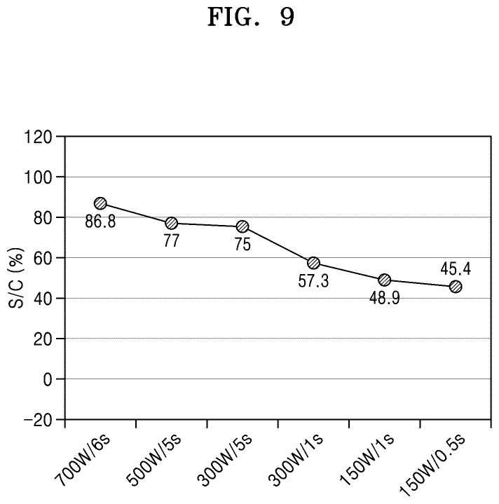

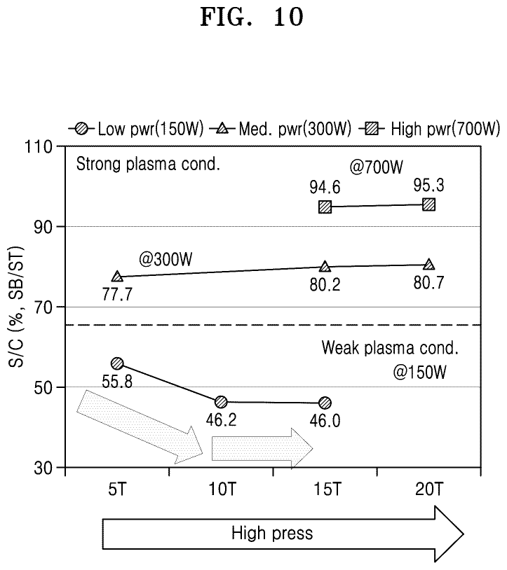

FIGS. 9 and 10 are views illustrating step coverage (S/C) characteristics of a SiN film on a side surface compared to an upper surface (side/top) of a patterned structure according to an RF voltage and a process pressure, according to an embodiment.

As shown in FIG. 9, it can be seen that the smaller the applied RF power and the shorter the application time, the lower the S/C of the SiN film on the patterned structure. In addition, as shown in FIG. 10, it can be seen that the lower the applied RF power and the higher the process pressure, the lower the S/C of the SiN film on the patterned structure. This means that when the applied RF power is small and the process pressure is high, the deposition on the inner surface of a gap is reduced, so that it is easy to form an air gap structure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing method comprising:
depositing an insulating layer on a patterned structure having a first protrusion and a second protrusion to form an air gap between the patterned structure and the insulating layer,
wherein an air gap is formed between the first protrusion and the second protrusion by maintaining pressure in a reaction space such that a mean free path of gas supplied to a reaction space decreases and by setting power of plasma such that the amount of ions generated in the reaction space decreases.

2. The substrate processing method of claim 1, wherein, while the insulating layer is deposited on the patterned structure, pressure in a reaction space is maintained at about 10 Torr to about 15 Torr.

3. The substrate processing method of claim 1, further comprising forming a first insulating layer, wherein the insulting layer is formed on the first insulating layer.

4. The substrate processing method of claim 3, wherein a step coverage of the insulating material is less than a step coverage of the first insulating material.

5. The substrate processing method of claim 3, wherein a hydrogen content of a second silicon source gas and a second reaction gas used for depositing the insulating material layer is higher than a hydrogen content of a first silicon source gas and a first reaction gas used to form the first insulating layer.

6. The substrate processing method of claim 1, comprising forming an air gap between the first protrusion and the second protrusion by depositing an insulating layer.

7. The substrate processing method of claim 1, comprising removing by-product between the first protrusion and the second protrusion.

8. The substrate processing method of claim 7, wherein the by-product is removed while depositing the insulating layer.

9. The substrate processing method of claim 7, wherein the by-product comprises at least one of a source gas, a molecule detached from or dangling-bonded to a molecule layer formed on an inner surface of the gap between the first and second protrusions, molecular fragments comprising the source gas, or a reaction gas.

10. The substrate processing method of claim 7, wherein, during the removing of the by-product, an etching material having an etch selectivity with the second insulating layer is used.

11. The substrate processing method of claim 7, wherein the forming the first insulating layer comprises:
forming a first silicon molecular layer on the first and second protrusions by supplying a first silicon-containing source gas;
purging the first silicon-containing source gas;
supplying a first reaction gas having reactivity with the first silicon molecular layer; and
purging the first reaction gas.

12. The substrate processing method of claim 11, wherein depositing an insulating layer comprises:
forming a second silicon molecular layer on the first insulating layer by supplying a second silicon-containing source gas;
purging the second silicon-containing source gas;
supplying a second reaction gas having reactivity with the second silicon molecular layer; and
purging the second reaction gas.

13. The substrate processing method of claim 1, further comprising:
applying a first hydrogen plasma on the first protrusion and the second protrusion before depositing the insulating layer.

14. The substrate processing method of claim 13, wherein a hydrogen-rich insulating layer including hydrogen-terminated sites is formed by the first hydrogen plasma.

15. The substrate processing method of claim 14, wherein a hydrogen monolayer is formed by performing a purge step between the applying of the first hydrogen plasma and the forming of the second silicon molecular layer.

16. The substrate processing method of claim 14, wherein, during the applying of the first hydrogen plasma, pressure in a reaction space is maintained at about 11 Torr to about 15 Torr.

17. The substrate processing method of claim 16, wherein, during the applying of the first hydrogen plasma, a power of plasma is set at about 100 W to about 400 W.

18. A substrate processing method comprising: forming an air gap between a patterned structure and an insulating layer by setting power of plasma to about 100 W to about 400 W and applying the power for about 0.1 second to about 1 second to deposit the insulating layer having a step coverage of about 60% or less on the patterned structure.

19. The substrate processing method of claim 18, wherein, while the insulating layer is deposited on the patterned structure, pressure in a reaction space is maintained at about 10 Torr to about 15 Torr.

20. The substrate processing method of claim 18, wherein by-product is removed while forming an air gap.
